(19) United States
(12) Patent Application Publication
(10) Pub. No.: US 2025/0366071 A1
(43) Pub. Date: Nov. 27, 2025

(54) CHANNEL EXTENSION STRUCTURES FOR SEMICONDUCTOR DEVICES

(71) Applicant: Taiwan Semiconductor Manufacturing Company, Ltd., Hsinchu (TW)

(72) Inventors: Yu-Shiang HUANG, Hsinchu City (TW); Cheng-Yi Peng, Taipei City (TW); Yen-Ting Chen, Taichung City (TW)

(73) Assignee: Taiwan Semiconductor Manufacturing Company, Ltd., Hsinchu (TW)

(21) Appl. No.: 19/295,585

(22) Filed: Aug. 9, 2025

Related U.S. Application Data
(63) Continuation of application No. 18/599,702, filed on Mar. 8, 2024.
(60) Provisional application No. 63/595,522, filed on Nov. 2, 2023.

(51) Int. Cl. H10D 30/67; H10D 30/01; H10D 30/43; H10D 62/10; H10D 64/01

(52) U.S. Cl. CPC H10D 30/6757; H10D 30/014; H10D 30/43; H10D 30/6735; H10D 62/10; H10D 64/018

(57) ABSTRACT

The present disclosure describes a semiconductor device having a channel extension structure. The semiconductor device includes a channel structure on a substrate. The channel structure includes a central portion and an end portion. The semiconductor device further includes a gate structure wrapped around the central portion of the channel structure, a source/drain (S/D) structure on the substrate and adjacent to the end portion of the channel structure, and an extension structure between the channel structure and the S/D structure. The extension structure has a first sidewall having a first height and adjacent to the end portion of the channel structure and a second sidewall having a second height and adjacent to the S/D structure greater than the first height.

### CROSS-REFERENCE TO RELATED APPLICATION

This application is a continuation application of U.S. Non-Provisional patent application Ser. No. 18/599,702, filed on Mar. 8, 2024, titled “Channel Extension Structures for Semiconductor Devices,” which claims the benefit of U.S. Provisional Patent Application No. 63/595,522, titled “Semiconductor Structure of Stacked Channels with Enlarged Extensions and Method of Forming the Same,” filed Nov. 2, 2023, the disclosure of which is incorporated herein by reference in its entirety.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs and fin field effect transistors (FinFETs). Such scaling down has increased the complexity of semiconductor manufacturing processes and increased the difficulty of process control in the semiconductor devices.

### BRIEF DESCRIPTION OF THE DRAWINGS

Aspects of the present disclosure are best understood from the following detailed description when read with the accompanying figures.

FIG. 1 illustrates an isometric view of a semiconductor device having a channel extension structure, in accordance with some embodiments.

FIGS. 2A-2B and 3A-3B illustrate partial cross-sectional views of a semiconductor device having a channel extension structure, in accordance with some embodiments.

FIG. 4 is a flow diagram of a method for fabricating a semiconductor device having a channel extension structure, in accordance with some embodiments.

FIGS. 5-24 illustrate partial cross-sectional views of a semiconductor device having a channel extension structure at various stages of its fabrication, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 20% of the value (e.g., ±1%, ±2%, ±3%, ±4%, ±5%, ±10%, ±20% of the value). These values are merely examples and are not intended to be limiting. The terms “about” and “substantially” can refer to a percentage of the values as interpreted by those skilled in relevant art(s) in light of the teachings herein.

With increasing demand for lower power consumption, higher performance, and smaller semiconductor devices, dimensions of semiconductor devices continue to scale down. The continuous scaling down of device dimensions and the increasing demand for device performance may require various process and material improvements, which can have multiple challenges. For example, a nanostructure transistor can have a gate structure wrapped around a channel structure to improve device performance. The nanostructure transistor can have inner spacers to isolate the gate structure from source/drain (S/D) structures. However, the inner spacers can decrease a height of the channel structure and reduce the contact areas between the channel structure and the S/D structures, which can increase the resistance between the channel structure and the S/D structure and degrade device performance of the nanostructure transistor.

Various embodiments in the present disclosure provide methods for forming a channel extension structure in a semiconductor device (e.g., a nanostructure transistor) and/or other semiconductor devices in an integrated circuit (IC). In some embodiments, a semiconductor device can include a channel structure on a substrate. The channel structure can include a central portion and an end portion. A gate structure can wrap around the central portion of the channel structure. A S/D structure can be disposed on the substrate and adjacent to the end portion of the channel structure. A channel extension structure can be disposed between the channel structure and the S/D structure. The channel extension structure can have a first sidewall adjacent to the end portion of the channel structure and a second sidewall adjacent to the S/D structure. The first sidewall can have a first height and the second sidewall can have a second height greater than the first height. With enlarged second height of the channel extension structure adjacent to the S/D structure, the contact area between the channel structure and the S/D structure can be increased, the resistance between the channel structure and the S/D structure can be decreased, and the device performance of the semiconductor device can be improved. Additionally, n-type transistors in the semiconductor device can have wider and thinner channel structures than p-type transistors in the semiconductor device. As a result, the device performance of the semiconductor device can be further improved.

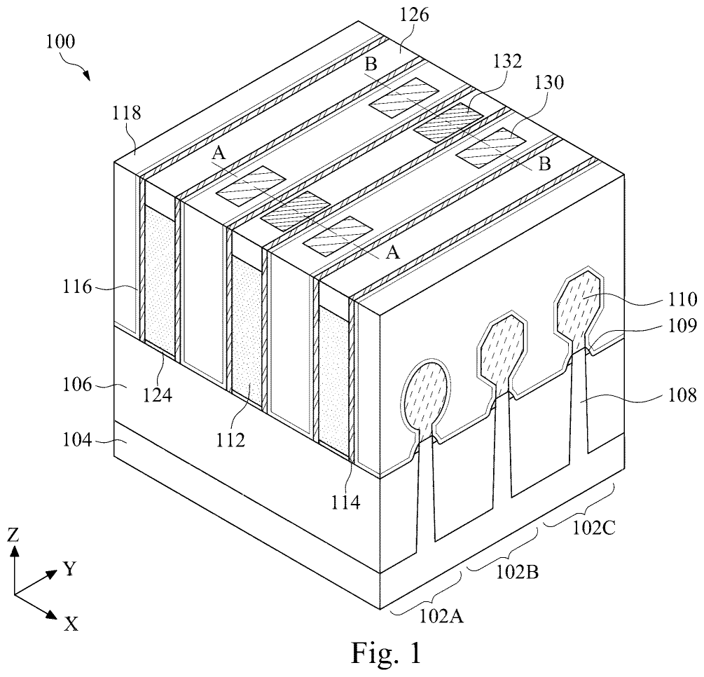

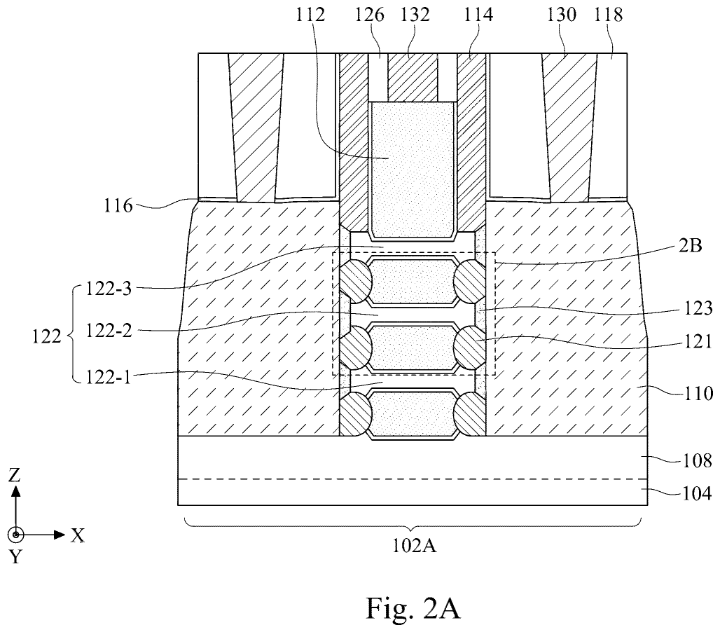

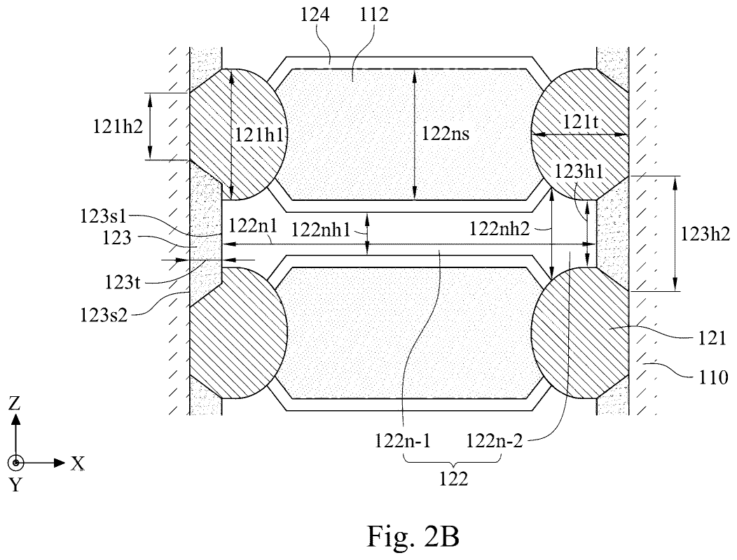

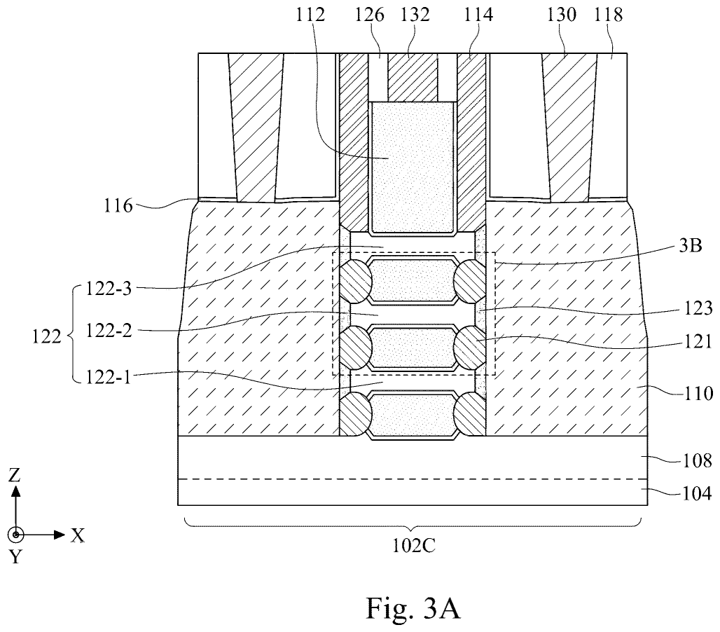

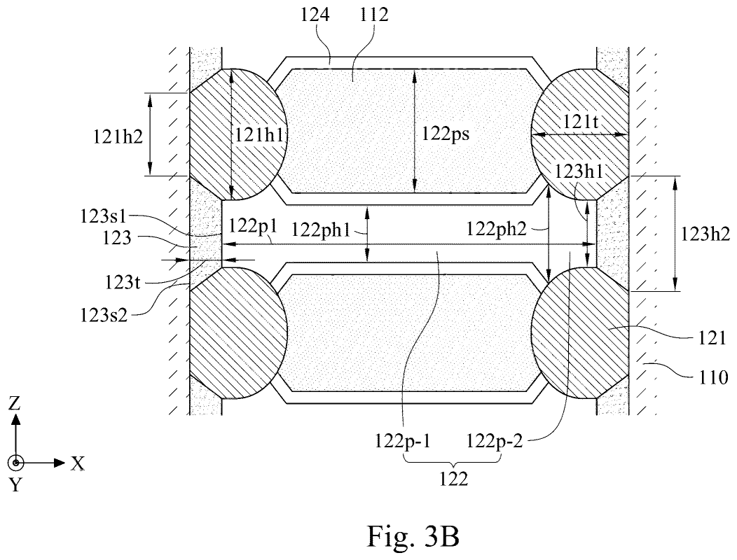

FIG. 1 illustrates an isometric view of a semiconductor device 100 having a channel extension structure, in accordance with some embodiments. FIGS. 2A and 3A illustrate partial cross-sectional views of semiconductor device 100 across line A-A and line B-B shown in FIG. 1, respectively, in accordance with some embodiments. FIGS. 2B and 3B illustrate partial cross-sectional views of enlarged areas 2B and 3B in semiconductor device 100 shown in FIGS. 2A and 3A, respectively, in accordance with some embodiments. In some embodiments, semiconductor device 100 can include transistors 102A-102C, as shown in FIG. 1. In some embodiments, transistors 102A-102C can include nanostructure transistors. The nanostructure transistors can include FinFETs, gate-all-around field effect transistors (GAA FETs), nanosheet transistors, nanowire transistors, multi-bridge channel transistors, nano-ribbon transistors, and other similar structured transistors. The nanostructure transistors can provide a channel in a stacked nanosheet/nanowire configuration.

In some embodiments, transistors 102A-102C can be n-type field-effect transistors (NFETs). In some embodiments, transistors 102A-102C can be p-type field-effect transistors (PFETs). In some embodiments, any of transistors 102A-102C can be an NFET or a PFET. In some embodiments, transistor 102A can be an NFET and transistors 102B and 102C can be PFETs. Though FIG. 1 shows three transistors, semiconductor device 100 can have any number of transistors. In addition, semiconductor device 100 can be incorporated into an IC through the use of other structural components, such as conductive vias, conductive lines, dielectric layers, passivation layers, and interconnects, which are not shown for simplicity. The discussion of elements of transistors 102A-102C with the same annotations applies to each other, unless mentioned otherwise. And like reference numerals generally indicate identical, functionally similar, and/or structurally similar elements.

Referring to FIGS. 1-3B, semiconductor device 100 having transistors 102A-102C can be formed on a substrate 104 and can be isolated by shallow trench isolation (STI) regions 106. Each of transistors 102A-102C can include fin structures 108, sidewall spacers 109, gate dielectric layer 124, gate structures 112, gate spacers 114, inner spacers 121, S/D structures 110, etch stop layer (ESL) 116, interlayer dielectric (ILD) layer 118, and gate capping structures 126. In some embodiments, as shown in FIGS. 2A and 3A, transistors 102A-102C can have nanostructures 122-1, 122-2, and 122-3 (collectively referred to as “nanostructures 122”) on fin structures 108.

Referring to FIGS. 1, 2A, and 3A, substrate 104 can include a semiconductor material, such as silicon. In some embodiments, substrate 104 includes a crystalline silicon substrate (e.g., wafer). In some embodiments, substrate 104 includes (i) an elementary semiconductor, such as germanium; (ii) a compound semiconductor including silicon carbide, gallium arsenide, gallium phosphide, indium phosphide, indium arsenide, and/or indium antimonide; (iii) an alloy semiconductor including silicon germanium carbide, silicon germanium, gallium arsenic phosphide, and/or aluminum gallium arsenide; or (iv) a combination thereof. Further, substrate 104 can be doped depending on design requirements (e.g., p-type substrate or n-type substrate). In some embodiments, substrate 104 can be doped with p-type dopants (e.g., boron, indium, aluminum, or gallium) or n-type dopants (e.g., phosphorus or arsenic).

STI regions 106 can provide electrical isolation between transistors 102A-102C and from neighboring transistors (not shown) on substrate 104 and/or neighboring active and passive elements (not shown) integrated with or deposited on substrate 104. STI regions 106 can be made of a dielectric material. In some embodiments, STI regions 106 can include silicon oxide, silicon nitride, silicon oxynitride, fluorine-doped silicate glass (FSG), a low-k dielectric material, and/or other suitable insulating materials. In some embodiments, STI regions 106 can include a multi-layered structure.

Referring to FIGS. 1-3B, nanostructures 122 and fin structures 108 can be formed on patterned portions of substrate 104. Embodiments of the nanostructures and fin structures disclosed herein may be patterned by any suitable method. For example, the nanostructures and fin structures may be patterned using one or more photolithography processes, including double-patterning or multi-patterning processes. Double-patterning or multi-patterning processes can combine photolithography and self-aligned processes, forming patterns that have, for example, pitches smaller than what is otherwise obtainable using a single, direct photolithography process. For example, a sacrificial layer is formed over a substrate and patterned using a photolithography process. Spacers can be formed alongside the patterned sacrificial layer using a self-aligned process. The sacrificial layer is then removed, and the remaining spacers can then be used to pattern the nanostructures and fin structures.

As shown in FIGS. 1-3B, nanostructures 122 and fin structures 108 can extend along an X-axis for transistors 102A-102C. In some embodiments, nanostructures 122 and fin structures 108 can be disposed on substrate 104. Nanostructures 122 can include a set of nanostructures 122-1, 122-2, and 122-3, which can be in the form of nanosheets, nanowires, or nano-ribbons. Each of nanostructures 122 can act as a channel structure and form a channel region underlying gate structures 112 of transistors 102A-102C. In some embodiments, nanostructures 122 and fin structures 108 can include semiconductor materials similar to or different from substrate 104. In some embodiments, nanostructures 122 and fin structures 108 can include silicon. In some embodiments, nanostructures 122 and fin structures 108 can include silicon germanium. The semiconductor materials of nanostructures 122 and fin structures 108 can be undoped or can be in-situ doped during their formation process. In some embodiments, as shown in FIGS. 2A-3B, nanostructures 122 under gate structures 112 can form channel regions of semiconductor device 100 and represent current carrying channel structures of semiconductor device 100. Though three layers of nanostructures 122 are shown in FIGS. 2A and 3A, transistors 102A-102C can have any number of nanostructures 122.

In some embodiments, for n-type transistors (e.g., transistor 102A shown in FIGS. 2A and 2B), nanostructures 122 can include a central portion 122n−1 wrapped around by gate structures 112 and an end portion 122n−2 between inner spacers 121. In some embodiments, central portion 122n−1 can have a height 122nh1 along a Z-axis ranging from about 3 nm to about 5 nm. In some embodiments, end portion 122n−2 can have a height 122nh2 along a Z-axis ranging from about 5 nm to about 10 nm. In some embodiments, a ratio between height 122nh2 to height 122nh1 can range from about 1.2 to about 1.8. In some embodiments, nanostructures 122 of n-type transistors can have a length 122nl along an X-axis ranging from about 15 nm to about 100 nm. In some embodiments, a spacing 122ns along a Z-axis between nanostructures 122 can range from about 9 nm to about 13 nm. The ranges of heights 122nh1 and 122nh2, the ratio, length 122nl, and spacing 122ns can improve gate control, device yield, and process window of the n-type transistors without ion mobility degradation in the channel region. If height 122nh1 is less than about 3 nm, height 122nh2 is greater than about 10 nm, or the ratio is greater than about 1.8, the ion mobility degradation in the channel region can increase and device performance can decrease. If height 122nh1 is greater than about 5 nm, height 122nh2 is less than about 5 nm, or the ratio is less than about 1.2, the gate control and process window can be degraded.

In some embodiments, for p-type transistors (e.g., transistor 102C shown in FIGS. 3A and 3B), nanostructures 122 can include a central portion 122p−1 wrapped around by gate structures 112 and an end portion 122p−2 between inner spacers 121. In some embodiments, central portion 122p−1 can have a height 122ph1 along a Z-axis ranging from about 4 nm to about 8 nm. In some embodiments, end portion 122p−2 can have a height 122ph2 along a Z-axis ranging from about 5 nm to about 10 nm. In some embodiments, a ratio between height 122ph2 to height 122ph1 can range from about 1.1 to about 1.4. In some embodiments, nanostructures 122 of p-type transistors can have a length 122pl along an X-axis ranging from about 10 nm to about 70 nm. In some embodiments, a spacing 122ps along a Z-axis between nanostructures 122 can range from about 7 nm to about 11 nm. The ranges of heights 122ph1 and 122ph2, the ratio, length 122pl, and spacing 122ps can improve device performance, device yield, and process window of the p-type transistors. If height 122ph1 is less than about 4 nm, height 122ph2 is greater than about 10 nm, or the ratio is greater than about 1.4, semiconductor device 100 can have worse gate control and decreased device performance. If height 122ph1 is greater than about 8 nm, height 122ph2 is less than about 5 nm, or the ratio is less than about 1.1, the gate control and process window can degrade.

In some embodiments, channel regions in p-type transistors can be thicker and shorter than channel regions in n-type transistors. For example, as shown in FIGS. 2A-3B, height 122ph1 can be greater than height 122nh1 and length 122pl can be less than length 122nl. In some embodiments, a difference between heights 122ph1 and 122nh1 can range from about 1 nm to about 5 nm. In some embodiments, a ratio of height 122ph1 to height 122nh1 can range from about 1.2 to about 2.0. In some embodiments, a difference between lengths 122nl and 122pl can range from about 5 nm to about 30 nm. In some embodiments, a ratio of length 122nl to length 122pl can range from about 1.2 to about 2.0. These ranges of heights 122nh1 and 122ph1, lengths 122nl and 122pl, the differences, and the ratios can improve device performance of both n-type and p-type transistors without degrading the gate control or the process window.

Referring to FIGS. 1-3B, gate dielectric layer 124 can be formed on nanostructures 122, fin structures 108, and STI regions 106. In some embodiments, gate dielectric layer 124 can be multi-layered structures and can include an interfacial layer and a high-k dielectric layer. In some embodiments, gate dielectric layer 124 can include no interfacial layer and a high-k dielectric layer in direct contact with nanostructures 122. In some embodiments, the interfacial layer can include silicon oxide formed by a deposition process or an oxidation process. In some embodiments, the interfacial layer can have a thickness ranging from about 0.1 nm to about 1.5 nm. In some embodiments, the high-k dielectric layer can include hafnium oxide, zirconium oxide, or other suitable high-k dielectric materials.

S/D structures 110 can be disposed on fin structures 108 and on opposing sides of gate structures 112. S/D structures 110 can function as S/D regions of transistors 102A-102C. In some embodiments, S/D structures 110 can have any geometric shape, such as a polygon, an ellipsis, and a circle. In some embodiments, S/D structures 110 can include an epitaxially-grown semiconductor material, such as silicon (e.g., the same material as substrate 104). In some embodiments, the epitaxially-grown semiconductor material can include an epitaxially-grown semiconductor material different from the material of substrate 104, such as silicon germanium and imparts a strain on the channel regions under gate structures 112. Since the lattice constant of such epitaxially-grown semiconductor material is different from the material of substrate 104, the channel regions are strained to increase carrier mobility in the channel regions of semiconductor device 100. The epitaxially-grown semiconductor material can include: (i) a semiconductor material, such as germanium and silicon; (ii) a compound semiconductor material, such as gallium arsenide and aluminum gallium arsenide; or (iii) a semiconductor alloy, such as silicon germanium and gallium arsenide phosphide.

In some embodiments, S/D structures 110 can include silicon and can be in-situ doped during an epitaxial growth process using n-type dopants, such as phosphorus and arsenic. In some embodiments, S/D structures 110 can include silicon, silicon germanium, germanium, or III-V materials (e.g., indium antimonide, gallium antimonide, or indium gallium antimonide) and can be in-situ doped during an epitaxial growth process using p-type dopants, such as boron, indium, and gallium. In some embodiments, S/D structures 110 can include one or more epitaxial layers, where each epitaxial layer can have different compositions.

In some embodiments, as shown in FIGS. 1-3B, gate structures 112 can be disposed on gate dielectric layer 124. In some embodiments, gate structures 112 can include one or more work function metal layers and a metal fill. The one or more work function metal layers can include work function metals to tune the threshold voltage (Vₜ) of transistors 102A-102C. In some embodiments, gate structures 112 for NFET and PFET devices can have the same work-function metal. In some embodiments, gate structures 112 for NFET and PFET devices can have different work-function metals. In some embodiments, as shown in FIG. 2A, each of nanostructures 122 can be wrapped around by gate structures 112, for which gate structures 112 can be referred to as “gate-all-around (GAA) structures” and transistors 102A-102C can also be referred to as “GAA FETs 102A-102C.” The one or more work function metal layers can wrap around nanostructures 122 and can include work function metals to tune the Vₜ of transistors 102A-102C. In some embodiments, transistors 102A-102C can include any number of work function metal layers for Vₜ tuning (e.g., ultra-low Vₜ, low Vₜ, and standard Vₜ).

In some embodiments, NFETs 102A-102C can include n-type work function metal layers. The n-type work function metal layers can include aluminum, titanium aluminum, titanium aluminum carbon, tantalum aluminum, tantalum aluminum carbon, tantalum silicon carbide, hafnium carbide, silicon, titanium nitride, titanium silicon nitride, or other suitable work function metals. In some embodiments, PFETs 102A-102C can include p-type work function metal layers. The p-type work function metal layers can include titanium nitride, titanium silicon nitride, tantalum nitride, tungsten carbon nitride, tungsten, molybdenum, or other suitable work function metals. In some embodiments, the work function metal layers can include a single metal layer or a stack of metal layers. The stack of metal layers can include work function metals having work-function values equal to or different from each other. In some embodiments, the metal fill can include titanium, tantalum, aluminum, cobalt, tungsten, nickel, ruthenium, or other suitable conductive materials.

Referring to FIGS. 1-3B, gate spacers 114 can be disposed on sidewalls of gate structures 112, sidewall spacers 109 can be disposed on sidewalls of fin structures 108, and inner spacers 121 can be disposed between gate structures 112 and S/D structures 110. Gate spacers 114, sidewall spacers 109, and inner spacers 121 can include insulating materials, such as silicon oxide, silicon nitride, silicon oxynitride, silicon carbonitride, silicon oxycarbide, silicon oxycarbonitride, a low-k material, and a combination thereof. In some embodiments, gate spacers 114, sidewall spacers 109, and inner spacers 121 can include a same insulating material. In some embodiments, gate spacers 114, sidewall spacers 109, and inner spacers 121 can include different insulating materials. Gate spacers 114, sidewall spacers 109, and inner spacers 121 can include a single layer or a stack of insulating layers. Gate spacers 114, sidewall spacers 109, and inner spacers 121 can have a low-k material with a dielectric constant less than about 3.9 (e.g., about 3.5, about 3.0, or about 2.8).

In some embodiments, as shown in FIGS. 2B and 3B, inner spacers 121 can have a thickness 121t along an X-axis ranging from about 4 nm to about 8 nm. In some embodiments, as shown in FIGS. 2B and 3B, inner spacers 121 can have a first height 121h1 along a Z-axis adjacent to gate structures 112 ranging from about 7 nm to about 10 nm and a second height 121h2 along a Z-axis adjacent to S/D structures 110 ranging from about 2 nm to about 6 nm. In some embodiments, second height 121h2 can be less than first height 121h1 such that contact areas between channel extension structures 123 and S/D structures 110 can be increased. In some embodiments, a ratio between second height 121h2 to first height 121h1 can range from about 1.5 to about 4.

In some embodiments, channel extension structures 123 can be disposed between nanostructures 122 and S/D structures 110. In some embodiments, channel extension structures 123 can include an epitaxially-grown semiconductor material, such as silicon. In some embodiments, channel extension structures 123 can include the same semiconductor material as nanostructures 122. The semiconductor materials of channel extension structures 123 can be undoped or can be in-situ doped during their formation process.

In some embodiments, as shown in FIGS. 2B and 3B, channel extension structures 123 can have a first sidewall 123s1 in contact with nanostructures 122 and a second sidewall 123s2 in contact with S/D structures 110. In some embodiments, first sidewall 123s1 can have a first height 123h1 along a Z-axis ranging from about 5 nm to about 9 nm. In some embodiments, second sidewall 123s2 can have a second height 123h2 along a Z-axis ranging from about 7 nm to about 12 nm. In some embodiments, second height 123h2 can be greater than first height 123h1 such that contact areas between channel extension structures 123 and S/D structures 110 can be increased and resistance between nanostructures 122 and S/D structures 110 can be reduced. In some embodiments, a difference between height 123h2 and height 123h1 can range from about 0.5 nm to about 5 nm. In some embodiments, a ratio of height 123h2 to height 123h1 can range from about 1.1 to about 2.5. If the difference is less than about 0.5 nm or the ratio is less than about 1.1, the contact areas between channel extension structures 123 and S/D structures 110 may not be increased and resistance between nanostructures 122 and S/D structures 110 may not be reduced. If the difference is greater than about 5 nm or the ratio is greater than about 2.5, isolation between gate structures 112 and S/D structures 110 may be degraded.

In some embodiments, as shown in FIGS. 2B and 3B, channel extension structures 123 can have thickness 123t along an X-axis ranging from about 0.5 nm to about 6 nm. In some embodiments, thickness 121t can be greater than thickness 123t to reduce S/D-gate short defects. In some embodiments, a ratio of thickness 121t to thickness 123t can range from about 1.5 to about 10. If thickness 123t is less than about 0.5 nm or the ratio is greater than about 10, the contact areas between channel extension structures 123 and S/D structures 110 may not be increased and resistance between nanostructures 122 and S/D structures 110 may not be reduced. If thickness 123t is greater than about 6 nm or the ratio is less than about 1.5, gate control may be degraded and S/D-gate short defects between gate structures 112 and S/D structures 110 may increase.

ESL 116 can be disposed on STI regions 106, S/D structures 110, and sidewalls of gate spacers 114 and sidewall spacers 109. ESL 116 can be configured to protect STI regions 106, S/D structures 110, and gate structures 112 during the formation of S/D contact structures 130 on S/D structures 110. In some embodiments, ESL 116 can include, for example, silicon oxide, silicon nitride, silicon oxynitride, silicon carbide, silicon carbonitride, boron nitride, silicon boron nitride, silicon carbon boron nitride, or a combination thereof.

ILD layer 118 can be disposed on ESL 116 over S/D structures 110 and STI regions 106. ILD layer 118 can include a dielectric material deposited using a deposition method suitable for flowable dielectric materials. For example, flowable silicon oxide can be deposited using flowable chemical vapor deposition (FCVD). In some embodiments, the dielectric material can include silicon oxide.

Referring to FIGS. 1-3B, gate capping structures 126 can be disposed on gate structures 112 and configured to protect underlying structures and/or layers during processing of semiconductor device 100. For example, gate capping structures 126 can act as an etch stop layer during the formation of S/D contact structures 130 on S/D structures 110. Gate capping structures 126 can include one or more insulating materials. In some embodiments, the insulating materials can include silicon nitride, silicon oxynitride, silicon carbide, silicon carbonitride, aluminum oxide, or other suitable materials.

In some embodiments, as shown in FIGS. 1-3B, semiconductor device 100 can further include S/D contact structures 130 and gate contact structures 132. In some embodiments, S/D contact structures 130 can be disposed on S/D structures 110 and gate contact structures 132 can be disposed on gate structures 112. In some embodiments, S/D contact structures 130 can include a silicide layer and a metal contact (not shown). In some embodiments, the silicide layer can include metal silicide and can provide a lower resistance interface between the metal contact and gate structures 112 or S/D structures 110. Examples of metal used for forming the metal silicide include cobalt, titanium, and nickel. In some embodiments, the metal contact and gate contact structures 132 can include conductive materials, such as tungsten, aluminum, and cobalt.

In some embodiments, semiconductor device 100 can further include metal lines, metal vias, interconnects, intermetallic dielectric layers, and other suitable layers and structures, which are not described in detail for clarity.

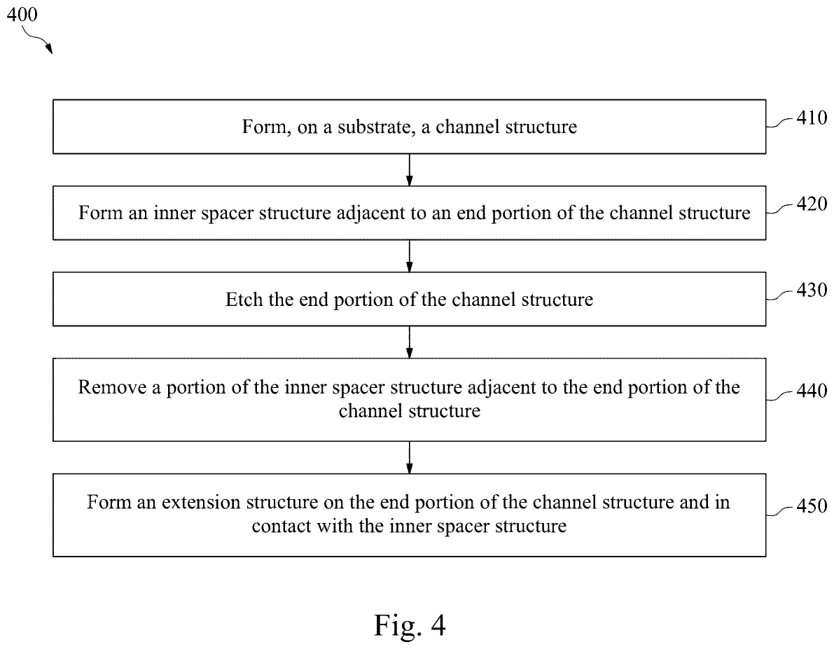

FIG. 4 is a flow diagram of a method 400 for fabricating semiconductor device 100 having a channel extension structure, in accordance with some embodiments. Method 400 may not be limited to nanostructure transistor devices and can be applicable to other devices that would benefit from the channel extension structure. Additional fabrication operations may be performed between various operations of method 400 and may be omitted merely for clarity and case of description. Additional processes can be provided before, during, and/or after method 400; one or more of these additional processes are briefly described herein. Moreover, not all operations may be needed to perform the disclosure provided herein. Additionally, some of the operations may be performed simultaneously or in a different order than shown in FIG. 4. In some embodiments, one or more other operations may be performed in addition to or in place of the presently-described operations.

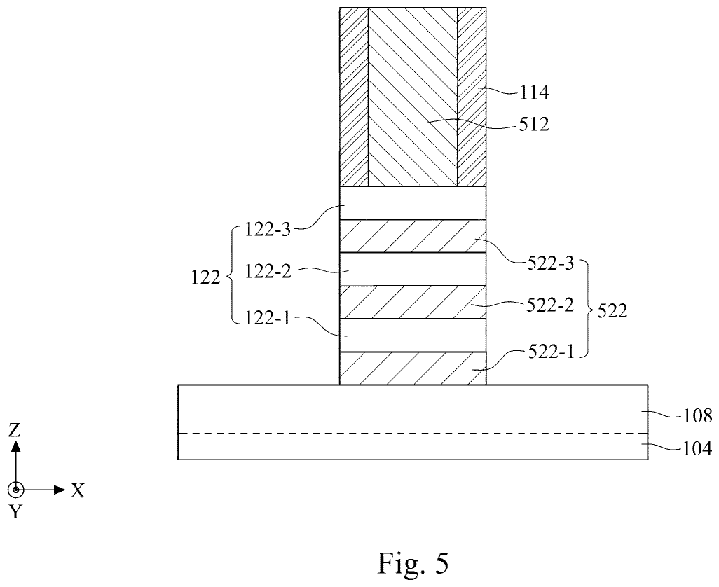

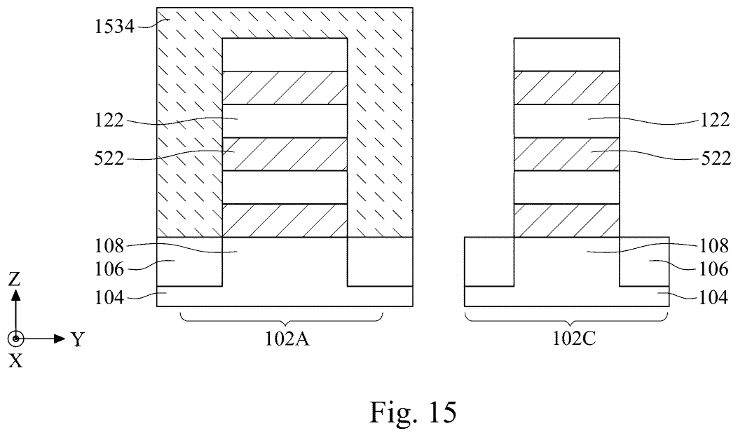

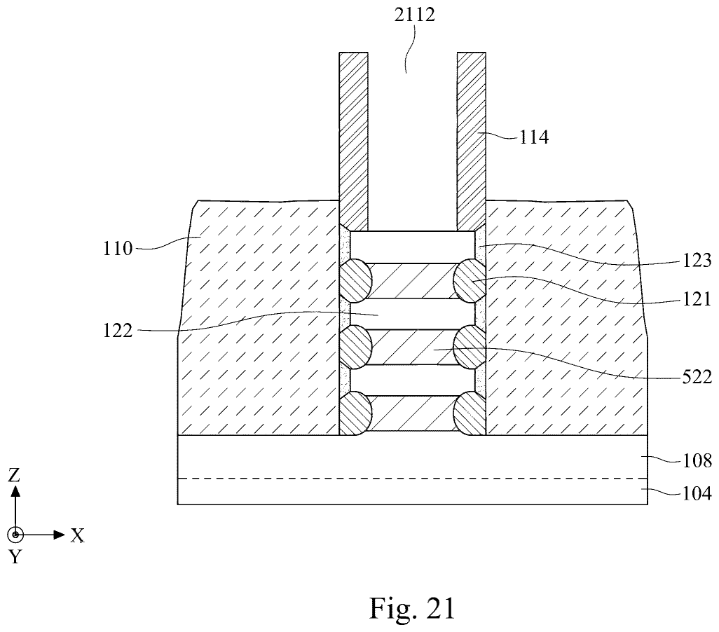

For illustrative purposes, the operations illustrated in FIG. 4 will be described with reference to the example fabrication process for fabricating semiconductor device 100 as illustrated in FIGS. 5-24. FIGS. 5-24 illustrate partial cross-sectional views of semiconductor device 100 having a channel extension structure at various stages of its fabrication, in accordance with some embodiments. FIGS. 5-14, 16, 18, and 20-22 illustrate partial cross-sectional views of semiconductor device 100 along line A-A or line B-B as shown in FIG. 1 at various stages of its fabrication, in accordance with some embodiments. FIGS. 15, 17, 19, and 24 illustrate partial cross-sectional views of semiconductor device 100 along a Y-axis as shown in FIG. 1 at various stages of its fabrication, in accordance with some embodiments. Elements in FIGS. 5-24 with the same annotations as elements in FIGS. 1-3B are described above.

In referring to FIG. 4, method 400 begins with operation 410 and the process of forming a channel structure on a substrate. For example, as shown in FIG. 5, nanostructures 122 and nanostructures 522-1, 522-2, and 522-3 (collectively referred to as “nanostructures 522”) stacked on fin structures 108 can be formed on substrate 104. In some embodiments, nanostructures 122 and 522 can be stacked in an alternate configuration. In some embodiments, nanostructures 122 and 522 can be epitaxially grown on substrate 104 and subsequently patterned to form nanostructures 122 and 522. In some embodiments, nanostructures 122 and 522 can be in the form of nanosheets, nanowires, or nano-ribbons. In some embodiments, nanostructures 122 and 522 can include semiconductor materials similar to or different from substrate 104. In some embodiments, fin structures 108 can include the same semiconductor material as substrate 104. In some embodiments, nanostructures 122 and 522 can include different semiconductor materials. For example, nanostructures 122 can include silicon and nanostructures 522 can include silicon germanium.

Embodiments of fin structures 108 and nanostructures 122 and 522 disclosed herein may be patterned by any suitable method. For example, the fin structures and the nanostructures may be patterned using one or more photolithography processes, including double-patterning or multi-patterning processes. Double-patterning or multi-patterning processes can combine photolithography and self-aligned processes, forming patterns that have, for example, pitches smaller than what is otherwise obtainable using a single, direct photolithography process. For example, a sacrificial layer is formed over a substrate and patterned using a photolithography process. Spacers can be formed alongside the patterned sacrificial layer using a self-aligned process. The sacrificial layer is then removed, and the remaining spacers can then be used to pattern the fin structures and the nanostructures.

The formation of nanostructures 122 and 522 can be followed by the formation of STI regions 106 between adjacent stacks of nanostructures 122 and 522, the formation of sacrificial gate structures 512 on nanostructures 122 and STI regions 106, the formation of gate spacers 114 on sacrificial gate structures 512, and the vertical recess of nanostructures 122 and 522 and STI regions 106, as shown in FIG. 5. In some embodiments, the vertical recess of nanostructures 122 and 522 can expose fin structures 108 and STI regions 106 to ensure complete removal of bottom nanostructures 522-1 on fin structures 108. These processes are not described in detail for clarity.

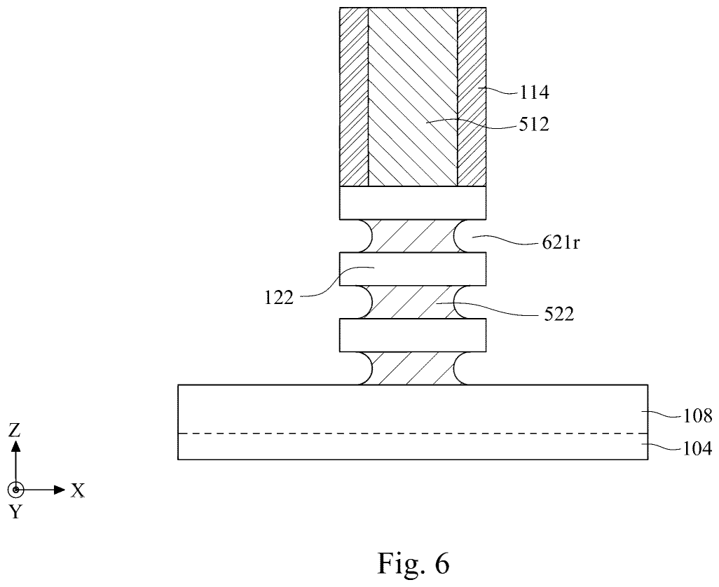

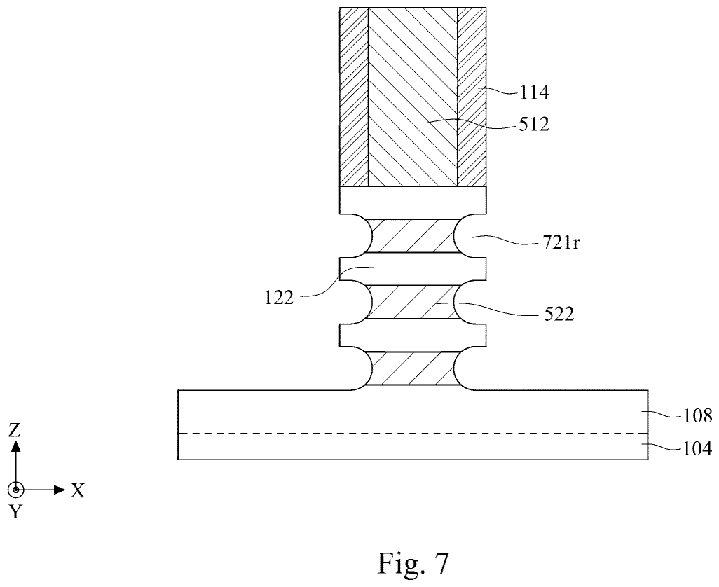

Referring to FIG. 4, in operation 420, an inner spacer structure is formed adjacent to an end portion of the channel structure. For example, as shown in FIGS. 6-9, inner spacers 121 can be formed adjacent to end portions of nanostructures 122. In some embodiments, the formation of inner spacers 121 can include the lateral recess of nanostructures 522 and the deposition and trim of a spacer layer. In some embodiments, with a higher selectivity (e.g., about 10 to about 50) between nanostructures 122 and 522, nanostructures 522 can be laterally etched to form recesses 621r between end portions of nanostructures 122, as shown in FIG. 6. In some embodiments, with a lower selectivity (e.g., about 2 to about 8) between nanostructures 122 and 522, nanostructures 522 can be laterally etched to form recesses 721r between end portions of nanostructures 122, as shown in FIG. 7.

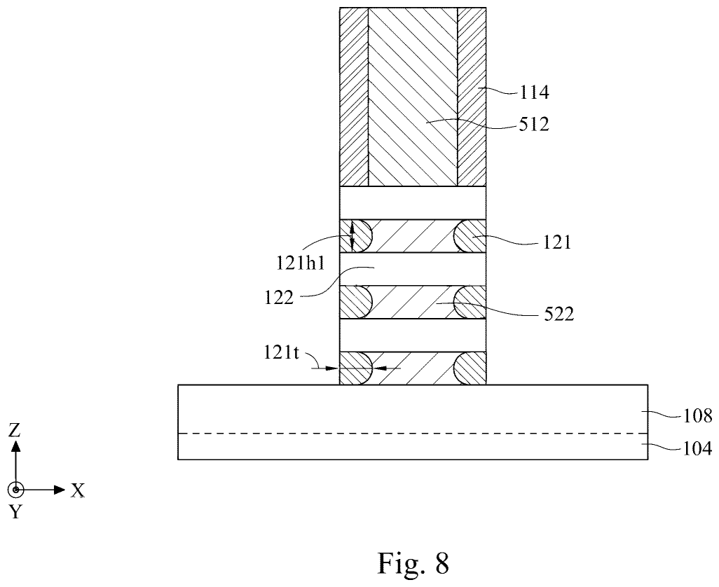

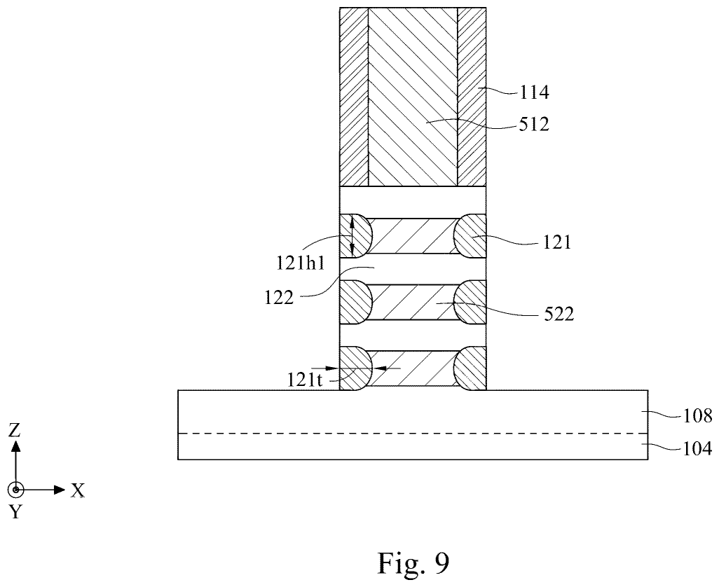

In some embodiments, a spacer layer can be conformally deposited in recesses 621 and 721 as well as on gate spacers 114 and nanostructures 122, followed by a directional etch to form inner spacers 121 in FIGS. 8 and 9. In some embodiments, the spacer layer can be deposited by atomic layer deposition (ALD), chemical vapor deposition (CVD), or other suitable deposition methods. In some embodiments, the spacer layer can include insulating materials, such as silicon oxide, silicon nitride, silicon oxynitride, silicon carbonitride, silicon oxycarbide, silicon oxycarbonitride, a low-k material, and a combination thereof. In some embodiments, the deposited spacer layer can completely fill recesses 621 and 721. In some embodiments, the spacer layer can be directionally etched to remove the spacer layer on gate spacers 114 and nanostructures 122. After the directional etching process, the remaining spacer layer in recesses 621 and 721 can form inner spacers 121. In some embodiments, inner spacers 121 can have a thickness 121t along an X-axis ranging from about 4 nm to about 8 nm.

In some embodiments, compared to inner spacers 121 formed after the higher selectivity lateral recess shown in FIG. 8, inner spacers 121 formed after the lower selectivity lateral recess shown in FIG. 9 can have a greater height 121h1 along a Z-axis. Additionally, end portions of nanostructures 122 formed after the higher selectivity lateral recess can have a greater height 122h2 along a Z-axis than the end portions of nanostructures 122 formed after the lower selectivity lateral recess. The shrinking of height 122h2 at the end portions of nanostructures 122 can reduce the contact areas between nanostructures 122 and subsequently formed S/D structures 110 and increase the resistance between nanostructures 122 and S/D structures 110.

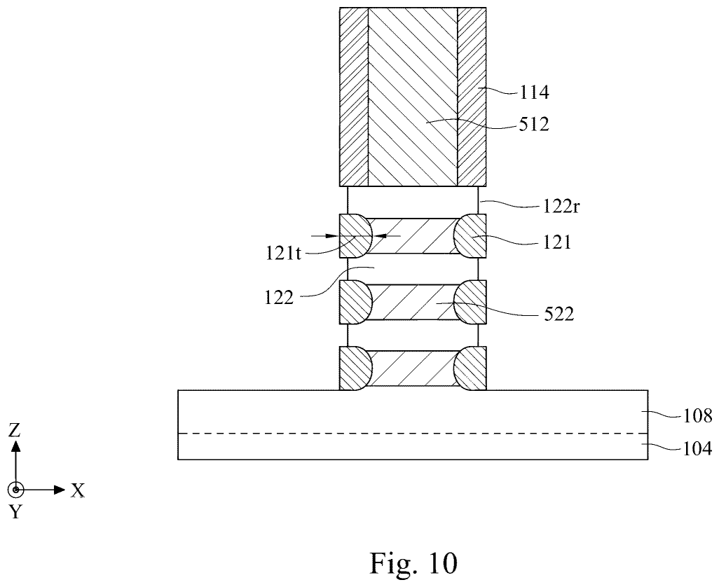

Referring to FIG. 4, in operation 430, the end portion of the channel structure is etched. For example, as shown in FIG. 10, end portions of nanostructures 122 can be laterally etched to form recesses 122r. In some embodiments, the end portions can be removed by etching gases including hydrogen fluoride, ammonia, nitrogen trifluoride, and hydrogen. In some embodiments, a plasma of the etching gases can be generated and radicals of the etching gases can be used to remove the end portions without plasma damage. In some embodiments, the lateral etching of the end portions can include an etchant generation process, an etching process, and an anneal process. During the etchant generation process, etchants can be generated from one or more of the etching gases. During the etching process, the etchants can react with the naturally grown oxide layer on nanostructures 122 and etching byproducts can be generated. During the anneal process, the etching byproducts can break down into gases that can evaporate from the end portions of nanostructures 122. In some embodiments, after the lateral etching of the end portions of nanostructures 122, a portion of side surfaces of inner spacers 121 adjacent to nanostructures 122 can be exposed, as shown in FIG. 10.

In some embodiments, recesses 122r can have a depth along an X-axis ranging from about 0.5 nm to about 6 nm. In some embodiments, the depth of recesses 122r may not be greater than thickness 121t of inner spacers 121 to avoid S/D-gate short defects. If the depth is less than about 0.5 nm, the contact areas between channel extension structures 123 and S/D structures 110 may not be increased and resistance between nanostructures 122 and S/D structures 110 may not be reduced. If the depth is greater than about 6 nm, gate control may be degraded and S/D-gate short defects between gate structures 112 and S/D structures 110 may increase.

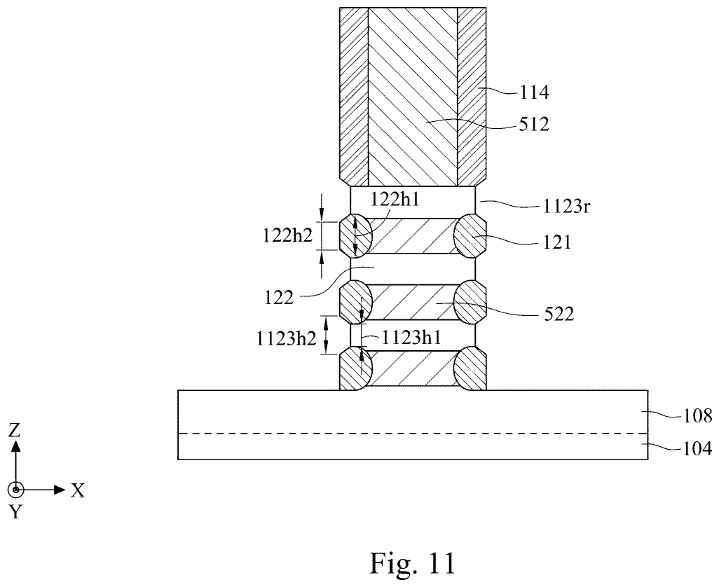

Referring to FIG. 4, in operation 440, a portion of the inner spacer structure adjacent to the end portion of the channel structure is removed. For example, as shown in FIG. 11, end portions of inner spacers 121 can be removed to form recesses 123r. In some embodiments, the end portions of inner spacers 121 can be etched by an atomic layer etching (ALE) process or other suitable etching processes. In some embodiments, the ALE process can use etching gases including carbon tetrafluoride, trifluoromethane, nitrogen trifluoride, oxygen, and argon. In some embodiments, the ALE process can be performed with a transformer coupled plasma (TCP). In some embodiments, the ALE process can include three states: an adsorption state, an activation/etching state, and a purge state. During the adsorption state, radicals of the etching gases can be adsorbed to end portions of inner spacers 121 and can modify the top layers of inner spacers 121. The TCP can operate at a power from about 20 W to about 80 W biased at about 1 MHz with a biasing power from about 2 W to about 6 W. During the activation/etching state, the adsorbed radicals can react with the modified layers of inner spacers 121 under a TCP power from about 150 W to about 250 W. During the purge state, the byproducts generated during the activation/etching state can be purged from inner spacers 121. In some embodiments, the ALE process can achieve self-limited removal of the modified layers.

In some embodiments, after the ALE process, end portions of inner spacers 121 can be removed and the openings of recesses 122r can be enlarged to form recesses 1123r, as shown in FIG. 11. In some embodiments, inner spacers 121 can have a first height 121h1 along a Z-axis adjacent to nanostructures 522 ranging from about 7 nm to about 10 nm and a second height 121h2 along a Z-axis adjacent to the end portions ranging from about 2 nm to about 6 nm. In some embodiments, second height 121h2 can be less than first height 121h1 such that contact areas between subsequently-formed channel extension structures 123 and S/D structures 110 can be increased. In some embodiments, a ratio between second height 121h2 to first height 121h1 can range from about 1.5 to about 4.

In some embodiments, recesses 1123r can have a first height 1123h1 along a Z-axis adjacent to nanostructures 122 ranging from about 5 nm to about 9 nm. In some embodiments, recesses 1123r can have a second height 1123h2 along a Z-axis adjacent to the openings ranging from about 7 nm to about 12 nm. In some embodiments, second height 1123h2 can be greater than first height 1123h1 such that contact areas between subsequently-formed channel extension structures 123 and S/D structures 110 can be increased and resistance between nanostructures 122 and S/D structures 110 can be reduced. In some embodiments, a difference between height 1123h2 and height 1123h1 can range from about 0.5 nm to about 5 nm. In some embodiments, a ratio of height 1123h2 to height 1123h1 can range from about 1.1 to about 2.5.

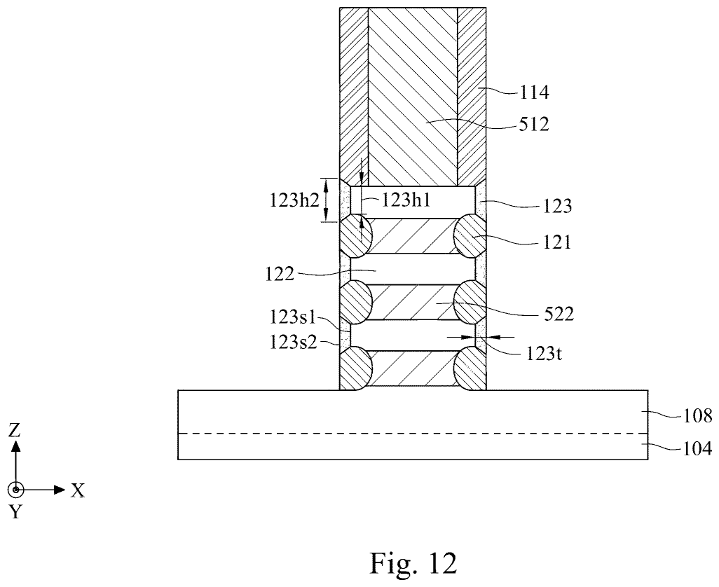

Referring to FIG. 4, in operation 450, an extension structure can be formed on the end portion of the channel structure and in contact with the inner spacer structure. For example, as shown in FIG. 12, channel extension structures 123 can be formed on end portions of nanostructures 122 and in contact with inner spacers 121. In some embodiments, channel extension structures 123 can be epitaxially grown in recesses 1123r on the end portions of nanostructures 122 by CVD or other suitable deposition methods. In some embodiments, channel extension structures 123 can include a semiconductor material, such as silicon. In some embodiments, channel extension structures 123 can include the same semiconductor material as nanostructures 122. The semiconductor materials of channel extension structures 123 can be undoped or can be in-situ doped during their formation process.

In some embodiments, as shown in FIG. 12, channel extension structures 123 can have a first sidewall 123s1 in contact with nanostructures 122 and a second sidewall 123s2 away from nanostructures 122. In some embodiments, first sidewall 123s1 can have a first height 123h1 along a Z-axis ranging from about 5 nm to about 9 nm. In some embodiments, second sidewall 123s2 can have a second height 123h2 along a Z-axis ranging from about 7 nm to about 12 nm. In some embodiments, second height 123h2 can be greater than first height 123h1 such that contact areas between channel extension structures 123 and subsequently-formed S/D structures 110 can be increased and resistance between nanostructures 122 and S/D structures 110 can be reduced. In some embodiments, a difference between height 123h2 and height 123h1 can range from about 0.5 nm to about 5 nm. In some embodiments, a ratio of height 123h2 to height 123h1 can range from about 1.1 to about 2.5. If the difference is less than about 0.5 nm or the ratio is less than about 1.1, the contact areas between channel extension structures 123 and S/D structures 110 may not be increased and resistance between nanostructures 122 and S/D structures 110 may not be reduced. If the difference is greater than about 5 nm or the ratio is greater than about 2.5, isolation between gate structures 112 and S/D structures 110 may be degraded.

In some embodiments, as shown in FIG. 12, channel extension structures 123 can have a thickness 123t along an X-axis ranging from about 0.5 nm to about 6 nm. In some embodiments, thickness 121t can be greater than thickness 123t to reduce S/D-gate short defects. In some embodiments, a ratio of thickness 121t to thickness 123t can range from about 1.5 to about 10. If thickness 123t is less than about 0.5 nm or the ratio is greater than about 10, the contact areas between channel extension structures 123 and S/D structures 110 may not be increased and resistance between nanostructures 122 and S/D structures 110 may not be reduced. If thickness 123t is greater than about 6 nm or the ratio is less than about 1.5, gate control may be degraded and S/D-gate short defects between gate structures 112 and S/D structures 110 may increase.

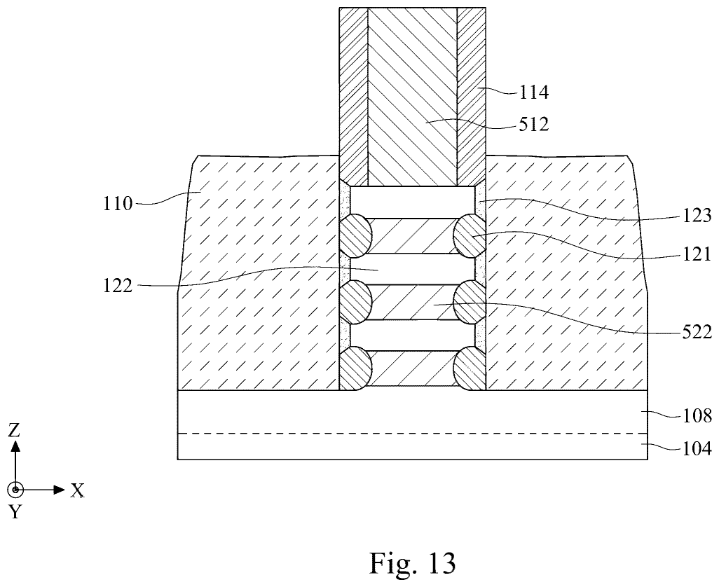

In some embodiments, the formation of channel extension structures 123 can be followed by the formation of S/D structures 110, as shown in FIG. 13. In some embodiments, channel extension structures 123 and S/D structures 110 can be formed separately. In some embodiments, channel extension structures 123 and S/D structures 110 can be formed in situ at a same process operation. In some embodiments, S/D structures 110 can be epitaxially grown on fin structures 108 and channel extension structures 123. S/D structures 110 can be in contact with second sidewall 121s2 of inner spacers 121. S/D structures 110 can function as S/D regions of transistors 102A-102C. In some embodiments, S/D structures 110 can have any geometric shape, such as a polygon, a cone, a diamond, an ellipsis, and a circle. In some embodiments, S/D structures 110 can include an epitaxially-grown semiconductor material, such as silicon (e.g., the same material as substrate 104). In some embodiments, S/D structures 110 can include an epitaxially-grown semiconductor material different from the material of substrate 104, such as silicon germanium, and can impart a strain on the channel regions under gate structures 112. In some embodiments, S/D structures 110 can include silicon and can be in-situ doped during the epitaxial growth process using n-type dopants, such as phosphorus and arsenic. In some embodiments, S/D structures 110 can include silicon, silicon germanium, germanium, or III-V materials (e.g., indium antimonide, gallium antimonide, or indium gallium antimonide) and can be in-situ doped during the epitaxial growth process using p-type dopants, such as boron, indium, and gallium. In some embodiments, S/D structures 110 can include one or more epitaxial layers, where each epitaxial layer can have different compositions.

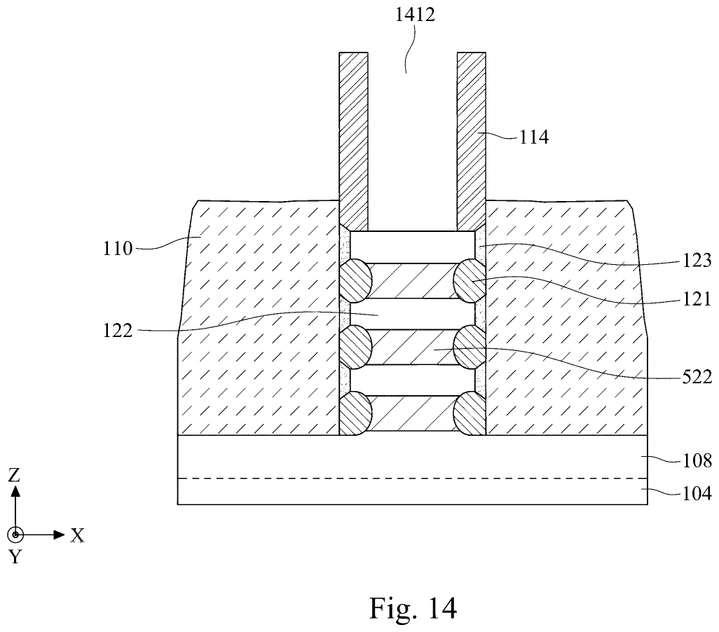

In some embodiments, the formation of S/D structures 110 can be followed by replacing sacrificial gate structures 512 with metal gate structures 112, as shown in FIGS. 14-24 and 1-3B. The replacement of sacrificial gate structures 512 can include removal of sacrificial gate structures 512, formation of n-type and p-type channel structures, and deposition of metal gate structures 112. In some embodiments, as shown in FIG. 14, a first etching process can remove sacrificial gate structures 512 and form an opening 1412 above nanostructures 122 and 522.

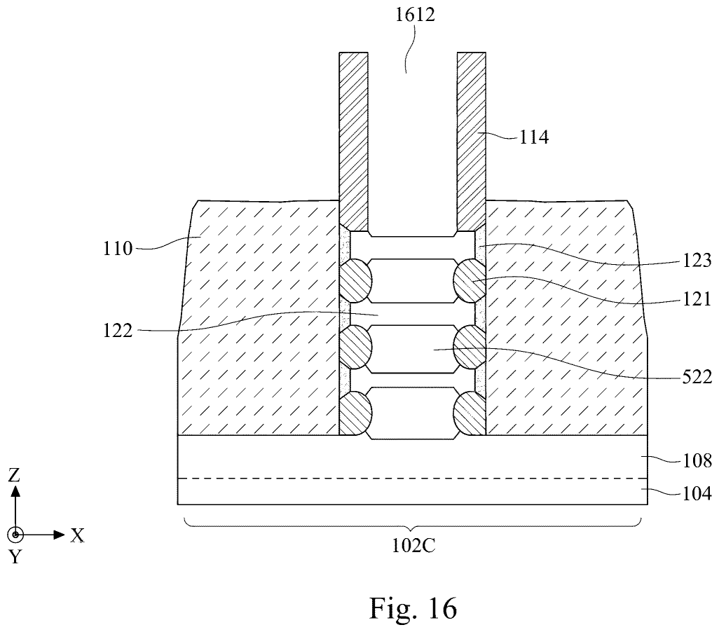

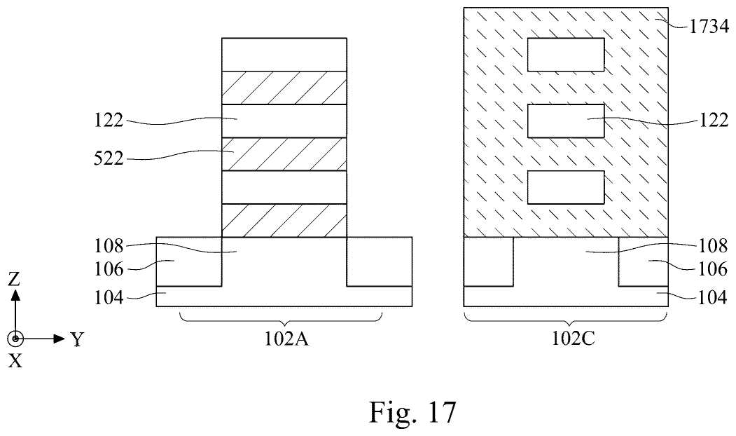

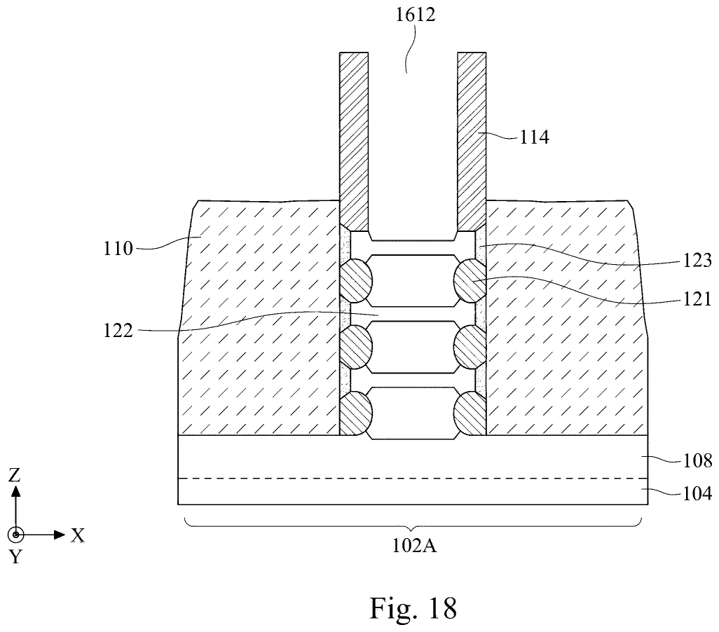

In some embodiments, as shown in FIGS. 14-19, n-type and p-type channel structures can be formed be in different process operations to have different dimensions. Two photomasks can be used to sequentially block n-type and p-type transistors. In some embodiments, as shown in FIG. 15, a blocking layer 1534 can be patterned to block n-type transistors (e.g., transistor 102A) and expose p-type transistors (e.g., transistor 102C). A second etching process can remove nanostructures 522 in p-type transistors (e.g., transistor 102C) and form an opening 1612 to expose nanostructures 122, as shown in FIG. 16. In some embodiments, the dimensions of nanostructures 122 in p-type transistors can be controlled by an etching time of the second etching process. As shown in FIG. 17, blocking layer 1534 can be removed and a blocking layer 1734 can be patterned to block p-type transistors (e.g., transistor 102C) and expose n-type transistors (e.g., transistor 102A). A third etching process can remove nanostructures 522 in n-type transistors (e.g., transistor 102A) and form an opening 1812 to expose nanostructures 122, as shown in FIG. 18. In some embodiments, the dimensions of nanostructures 122 in n-type transistors can be controlled by an etching time of the third etching process.

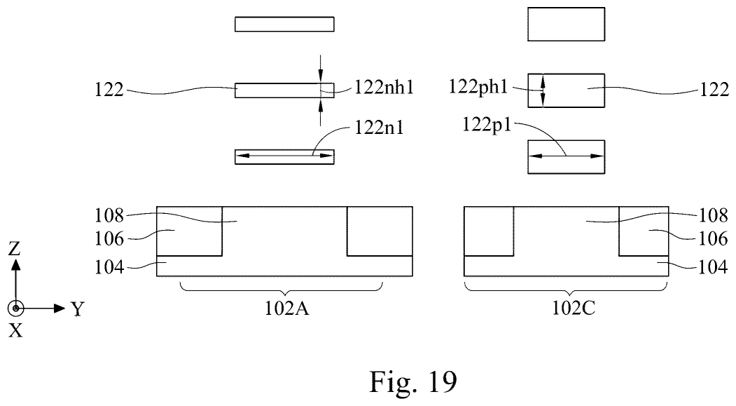

In some embodiments, the second etching process and the third etching process can have different etching selectivity and etching times to form nanostructures 122 with different heights and lengths in n-type and p-type transistors. For example, as shown in FIG. 19, after removal of blocking layer 1734, n-type transistors (e.g., transistor 102A) and p-type transistors (e.g., transistor 102C) can have different heights and lengths. In some embodiments, n-type transistors (e.g., transistor 102A) can have height 122nh1 along a Z-axis ranging from about 3 nm to about 5 nm and length 122nl along an X-axis ranging from about 15 nm to about 100 nm. In some embodiments, p-type transistors (e.g., transistor 102C) can have height 122ph1 along a Z-axis ranging from about 4 nm to about 8 nm and length 122pl along an X-axis ranging from about 10 nm to about 70 nm. In some embodiments, channel structures in p-type transistors can be thicker and shorter than channel structures in n-type transistors. As shown in FIG. 19, height 122ph1 can be greater than height 122nh1 and length 122pl can be less than length 122nl. In some embodiments, a difference between heights 122ph1 and 122nh1 can range from about 1 nm to about 5 nm. In some embodiments, a ratio of height 122ph1 to height 122nh1 can range from about 1.2 to about 2.0. In some embodiments, a difference between lengths 122nl and 122pl can range from about 5 nm to about 30 nm. In some embodiments, a ratio of length 122nl to length 122pl can range from about 1.2 to about 2.0. These ranges of heights 122nh1 and 122ph1, lengths 122nl and 122pl, the differences, and the ratios can improve device performance of both n-type and p-type transistors without degrading the gate control or the process window.

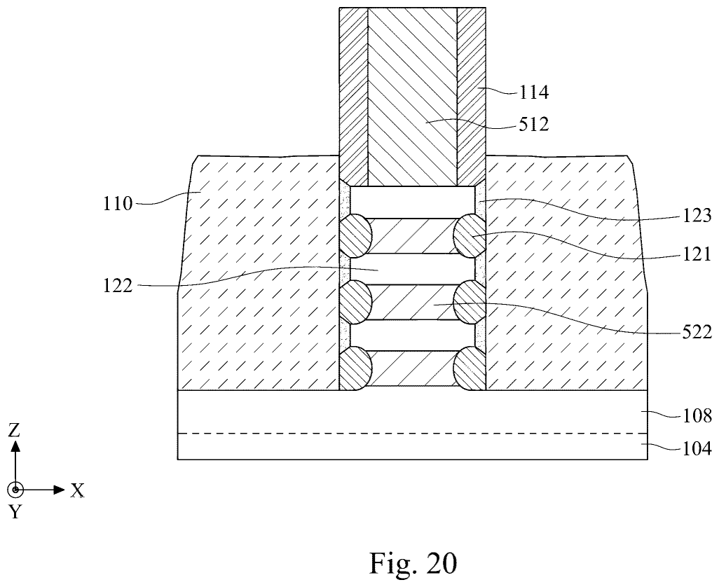

In some embodiments, as shown in FIGS. 20-24, n-type and p-type channel structures can be formed in the same process operation while having different dimensions. In some embodiments, as shown in FIG. 20, an anneal process can be performed after the formation of S/D structures. Dopants in n-type and p-type S/D structures can diffuse into channel extension structures 123 and nanostructures 122. In some embodiments, n-type dopants (e.g., phosphorus) in S/D structures 122 can diffuse into nanostructures 122 in n-type transistors (e.g., transistor 102A). In some embodiments, p-type dopants (e.g., boron) in S/D structures 122 can diffuse into nanostructures 122 in p-type transistors (e.g., transistor 102C). Nanostructures 122 doped with different dopants can have different etching rates. For example, nanostructures 122 doped with n-type dopants (e.g., phosphorus) can have a higher etching rate and nanostructures 122 doped with p-type dopants (e.g., boron) can have a lower etching rate. In some embodiments, the first etching process can remove sacrificial gate structures 512 in both n-type and p-type transistors and form an opening 2112 above nanostructures 122 and 522.

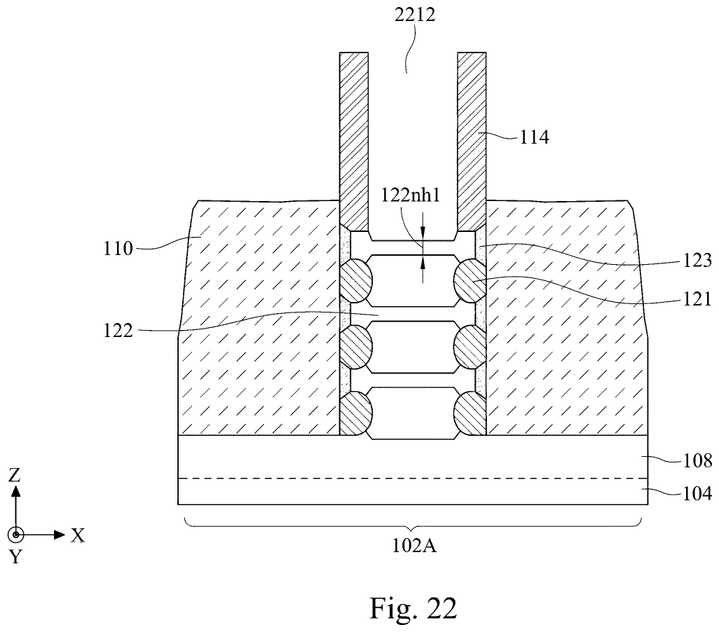

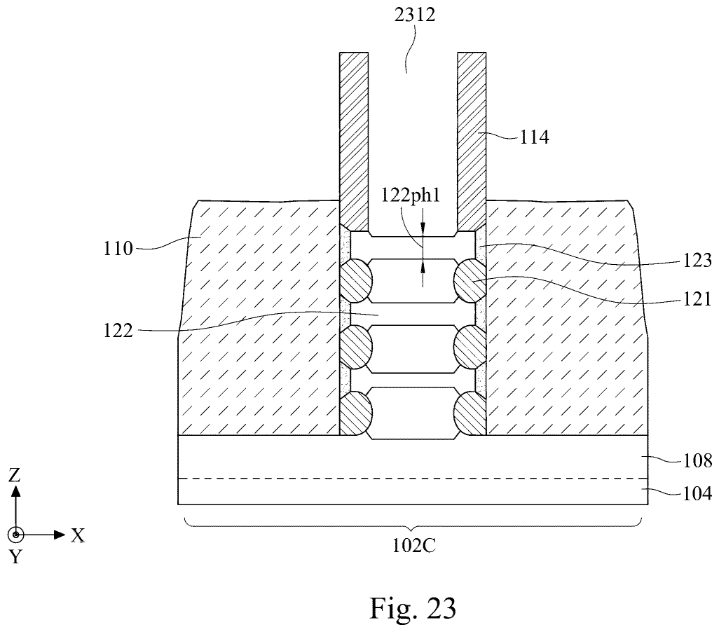

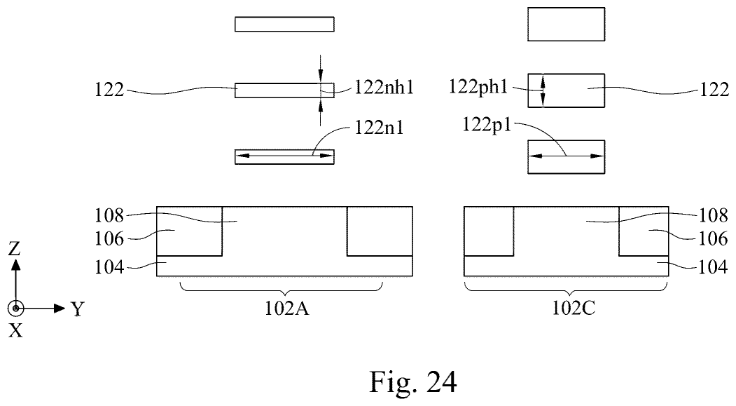

In some embodiments, a fourth etching process can remove nanostructures 522 in both n-type and p-type transistors and form openings 2212 and 2312 to expose nanostructures 122. In some embodiments, due to different dopants in the n-type and p-type transistors, the fourth etching process can have different etching rates for nanostructures 122 in n-type and p-type transistors. For example, the fourth etching process can remove more nanostructures 122 in n-type transistors (e.g., transistor 102A as shown in FIG. 22) and less nanostructures 122 in p-type transistors (e.g., transistor 102C as shown in FIG. 23). In some embodiments, after the fourth etching process, n-type transistors (e.g., transistor 102A) can have height 122nh1 and length 122nl and p-type transistors (e.g., transistor 102C) can have height 122ph1 and length 122pl. As shown in FIG. 24, height 122ph1 can be greater than height 122nh1 and length 122pl can be less than length 122nl, similar to the dimensions in FIG. 19. These different heights 122nh1 and 122ph1 and lengths 122nl and 122pl can improve device performance of both n-type and p-type transistors without degrading the gate control or the process window.

In some embodiments, metal gate structures 112 can be deposited between gate spacers 114 and inner spacers 121 to wrap around nanostructures 122, as shown in FIGS. 1-3B. In some embodiments, the formation of metal gate structures 112 can be followed by the formation of gate capping structures 126, the formation of S/D contact structures 130, the formation of gate contact structures 132, and other suitable processes to form semiconductor device 100 as shown in FIGS. 1-3B. These processes are not described in detail for clarity.

Various embodiments in the present disclosure provide methods for forming channel extension structures 123 in semiconductor device 100. In some embodiments, semiconductor device 100 can include nanostructures 122 on substrate 104. Nanostructures 122 can include central portions 122n−1 and 122p−1 and end portion 122n−2 and 122p−2. Gate structures 112 can wrap around the central portions of nanostructures 122. S/D structures 110 can be disposed on substrate 104 and adjacent to the end portions of nanostructures 122. Channel extension structures 123 can be disposed between nanostructures 122 and S/D structures 110. Channel extension structures 123 can have first sidewall 123s1 adjacent to the end portions of nanostructures 122 and a second sidewall 123s2 adjacent to S/D structures 110. First sidewall 123s1 can have first height 123h1 and second sidewall 123s2 can have second height 123h2 greater than first height 123h1. With enlarged second height 123h2 of channel extension structures 123 adjacent to S/D structures 110, the contact area between nanostructures 122 and S/D structures 110 can be increased, the resistance between nanostructures 122 and S/D structures 110 can be decreased, and the device performance of semiconductor device 100 can be improved. Additionally, n-type transistors in semiconductor device 100 can have wider and thinner nanostructures 122 than p-type transistors in semiconductor device 100. As a result, the device performance of semiconductor device 100 can be further improved.

In some embodiments, a semiconductor structure includes a channel structure on a substrate, an extension structure in contact with the end portion of the channel structure, and a source/drain (S/D) structure on the substrate and in contact with the extension structure. The channel structure includes a central portion having a first height and an end portion having a second height greater than the first height. The extension structure has a third height greater than the second height. The extension structure is between the channel structure and the S/D structure.

In some embodiments, a semiconductor device includes a channel structure on a substrate. The channel structure includes a central portion and an end portion. The semiconductor device further includes a gate structure wrapped around the central portion of the channel structure, a source/drain (S/D) structure on the substrate and adjacent to the end portion of the channel structure, and an extension structure between the channel structure and the S/D structure. A first sidewall of the extension structure adjacent to the end portion of the channel structure has a first height and a second sidewall of the extension structure adjacent to the S/D structure has a second height greater than the first height.

In some embodiments, a method includes forming a channel structure on a substrate, forming an inner spacer structure adjacent to an end portion of the channel structure, etching the end portion of the channel structure, removing a portion of the inner spacer structure adjacent to the end portion of the channel structure, and forming an extension structure on the end portion of the channel structure and in contact with the inner spacer structure.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a stack of nanostructures on a substrate, wherein the stack of nanostructures comprise a central portion having a first height and an end portion having a second height greater than the first height;
an inner spacer structure between the end portion of adjacent nanostructures in the stack of nanostructures;
an extension structure in contact with the inner spacer structure and the end portion of the stack of nanostructures; and
a source/drain (S/D) structure on the substrate, wherein the extension structure is surrounded by the inner spacer structure, the S/D structure, and the end portion of the stack of nanostructures.

2. The semiconductor structure of claim 1, wherein a ratio of the second height to the first height ranges from about 1.1 to about 1.8.

3. The semiconductor structure of claim 1, wherein the extension structure has a third height adjacent to the end portion of the stack of nanostructures and a fourth height adjacent to the S/D structure greater than the third height.

4. The semiconductor structure of claim 3, wherein a ratio of the fourth height to the second height ranges from about 1.1 to about 1.5.

5. The semiconductor structure of claim 1, further comprising an additional inner spacer structure between the end portion of the stack of nanostructures, wherein the extension structure is between the inner spacer structure and the additional inner spacer structure.

6. The semiconductor structure of claim 1, wherein the inner spacer structure has a fourth height adjacent to the end portion of the stack of nanostructures and a fifth height adjacent to the S/D structure less than the fourth height.

7. The semiconductor structure of claim 1, wherein the extension structure comprises an epitaxial semiconductor material.

8. The semiconductor structure of claim 1, further comprising an additional stack of nanostructures on the substrate having a conductivity type different from that of the stack of nanostructures, wherein the additional the stack of nanostructures comprise an additional central portion having a third height greater than the first height.

9. The semiconductor structure of claim 8, wherein a first spacing between adjacent nanostructures in the stack of nanostructures is greater than a second spacing between adjacent nanostructures in the additional stack of nanostructures.

10. The semiconductor structure of claim 1, wherein the extension structure is between the S/D structure and the end portion of the stack of semiconductor layers.

11. A semiconductor device, comprising:
a stack of nanostructures on a substrate, wherein the stack of nanostructures comprise a central portion between two end portions, and wherein the central portion has a first height and each of the end portion has a second height greater than the first height;
a gate structure wrapped around the central portion of the stack of nanostructures;
first and second source/drain (S/D) structures on the substrate and adjacent to the two end portions of the stack of nanostructures, respectively; and
an extension structure between the first S/D structures and one of the two end portions of the stack of nanostructures.

12. The semiconductor device of claim 11, wherein a first sidewall of the extension structure in contact with the stack of nanostructures has a third height and a second sidewall of the extension structure in contact with the first S/D structure has a second height greater than the first height.

13. The semiconductor device of claim 12, wherein the third height is greater than the first height.

14. The semiconductor device of claim 11, further comprising an additional stack of nanostructures on the substrate having a conductivity type different from the stack of nanostructures, wherein the additional stack of nanostructures comprise an additional central portion thicker than the central portion of the stack of nanostructures.

15. The semiconductor device of claim 11, further comprising an inner spacer structure surrounded by the gate structure, the extension structure, the first and second S/D structures, and the two end portions of the stack of nanostructures.

16. The semiconductor device of claim 15, wherein the inner spacer structure has a third height adjacent to the gate structure and a fourth height adjacent to the first and second S/D structures less than the third height.

17. A method, comprising:
forming first and second nanostructures on a substrate, wherein the first and second nanostructures comprise different semiconductor materials;
replacing an end portion of the first nanostructure with an inner spacer structure;
etching an end portion of the second nanostructure;
removing a portion of the inner spacer structure adjacent to the end portion of the second nanostructure; and
forming an extension structure on the end portion of the second nanostructure, wherein the extension structure is in contact with the inner spacer structure and the end portion of the second nanostructure.

18. The method of claim 17, wherein etching the end portion of the second nanostructure comprises laterally recessing the second nanostructure.

19. The method of claim 17, further comprising:
removing a central portion of the first nanostructure;
etching a central portion of the second nanostructure; and
forming a gate structure wrapping around the central portion of the second nanostructure, wherein the gate structure is in contact with the inner spacer structure.

20. The method of claim 17, further comprising forming a source/drain structure on the substrate and in contact with the extension structure and the inner spacer structure.
